(19) United States
(12) Patent Application Publication
(10) Pub. No.: US 2014/0169402 A1
(43) Pub. Date: Jun. 19, 2014

(54) TEMPERATURE MONITOR FOR DEVICES IN AN ION IMPLANT APPARATUS

(71) Applicant: Varian Semiconductor Equipment Associates, Inc., Gloucester, MA (US)

(72) Inventors: Aaron P. Webb, Austin, TX (US); Benjamin B. Riordon, Newburyport, MA (US); Charles T. Carlson, Cedar Park, TX (US); Christopher N. Grant, Dripping Springs, TX (US); Luke Bonecutter, Cedar Park, TX (US); William T. Weaver, Austin, TX (US)

(73) Assignee: Varian Semiconductor Equipment Associates, Inc., Gloucester, MA (US)

(21) Appl. No.: 14/101,954

(22) Filed: Dec. 10, 2013

Related U.S. Application Data
(60) Provisional application No. 61/736,701, filed on Dec. 13, 2012.

(51) Int. Cl. G01N 25/00; C23C 14/48; C23C 14/04; G01N 21/84; G01B 11/00

(52) U.S. Cl. CPC G01N 25/00; G01N 21/84; G01B 11/00; C23C 14/042; C23C 14/48
USPC 374/142; 118/712; 248/542

(57) ABSTRACT

An ion implant apparatus configured to measure the temperature or monitor the degradation of components in the apparatus is provided. The ion implant apparatus may include a platen configured to move in a first direction, a mask frame to hold one or more masks disposed on the platen, a first optical sensor configured to project an optical beam to a second optical sensor, and a measurement bar disposed on the mask frame, the measurement bar raised above the surface of the mask frame to interrupt the optical beam when the platen moves in the first direction.

### RELATED APPLICATIONS

This application claims the benefit of U.S. Provisional Application Ser. No. 61/736,701 filed Dec. 13, 2012, entitled “Monitoring Temperature of a Device Exposed to an Ion Beam.”

### FIELD

The present embodiments relate to ion implanters, to measuring the temperature or degradation of devices in an ion implant apparatus, and particularly to measuring the temperature of devices exposed to an ion beam.

### BACKGROUND

Ion implanters are widely used in electronic device fabrication, including semiconductor manufacturing to control device properties. In a typical ion implanter, ions generated from an ion source are directed as an ion beam through a series of beam-line components that may include one or more analyzing magnets and a plurality of electrodes that provide electric fields to tailor the ion beam properties. The analyzing magnets select desired ion species, filter out contaminant species and ions having undesirable energies, and adjust ion beam quality at a target wafer. Suitably shaped electrodes may modify the energy and the shape of an ion beam.

Additionally, masks may be placed over the target wafer to block areas of the target wafer from being exposed to the ion beam. As will be appreciated, mask alignment is critical to correct implantation. More specifically, properly aligning the mask is required to ensure that the ions are implanted at desired locations in the target wafer. The masking components are often required to be at process temperature to be correctly aligned. Conventional approaches use a thermocouple on the masking component, a viewport with a laser, or an infrared thermometer. Additionally, masking components generally degrades over time (e.g., as they are repeatedly heated and cooled, exposed to repeated ion beams, etc.) leaving the need to routinely check the condition of the masking components. Typically, this requires that the process chamber be vented, or requires using an inspection camera and a viewport. However, such conventional techniques use wires (e.g., in the case of a thermocouple) that may get in the way as the masking equipment is handed of to the platen in the process chamber; or these approaches require expensive equipment such as lasers, inspection cameras, or the like.

Thus, improvements in measuring the temperature of masking components in the process chamber and monitoring the degradation of the masking component are needed.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, a mask frame to hold one or more masks is provided. The mask frame may include a measurement bar disposed on the mask frame, the measurement bar raised above the surface of the mask frame.

In one embodiment, a method of measuring a temperature of a component in an ion implant apparatus is provided. The method may include projecting an optical beam from a first optical sensor to a second optical sensor, scanning a mask frame having a measurement bar disposed therein in a first direction, the measurement bar raised above the surface of the mask frame such that as the mask frame is scanned in the first direction the measurement bar interrupts the optical beam, determining a dimension of the measurement bar based at least in part on the measurement bar interrupting the optical beam, and determining a temperature of a component in the ion implant apparatus based at least in part on the determined dimension

### BRIEF DESCRIPTION OF THE DRAWINGS

FIGS. 1-2 depict perspective views of components of an ion implant apparatus including measurement bars to measure the temperature of the components or monitor the condition of the components;

FIGS. 3A-3B depict a block diagram of a mask frame including measurement bars to measure the temperature or monitor the condition of the mask frame; and

FIG. 4 depicts a flow diagram of a method of measuring the temperature of components of an ion implant apparatus, all arranged according to at least one embodiment of the present disclosure.

### DETAILED DESCRIPTION

The present embodiments will now be described more fully hereinafter with reference to the accompanying drawings, in which some embodiments are shown. The subject matter of the present disclosure, however, may be embodied in many different forms and should not be construed as limited to the embodiments set forth herein. Rather, these embodiments are provided so that this disclosure will be thorough and complete, and will fully convey the scope of the subject matter to those skilled in the art. In the drawings, like numbers refer to like elements throughout.

Various embodiments described herein provide apparatuses and methods to measure the temperature of components in an ion implant apparatus. Additionally, various embodiments provide apparatuses and methods to monitor the condition of the component. In particular, measurement bars may be disposed on the components whose temperature and/or degradation are to be measured. A beam is then passed over the measurement bars to measure a dimension of the measurement bars. Additionally, any discontinuities in the measurement bars may be detected. The dimension and/or discontinuities of the measurement bars may be used to determine the temperature and/or level of degradation of the components.

During operation of an ion implant apparatus it may be necessary to determine the temperature of the components, in order to align a mask with a workpiece, or the like. Additionally, it may be advantageous to monitor the condition of the components to determine if any degradation of the components such as a mask has occurred. As will be explained in greater detail below, in accordance with the present embodiments while the components are scanned in a given direction optical sensors and a controller may be used to measure a dimension (e.g., length, width, or the like) of measurement bars disposed on the components to determine a temperature of ones of the components. Additionally, degradation of the measurement bars may be identified and used to determine a condition of ones of the components.

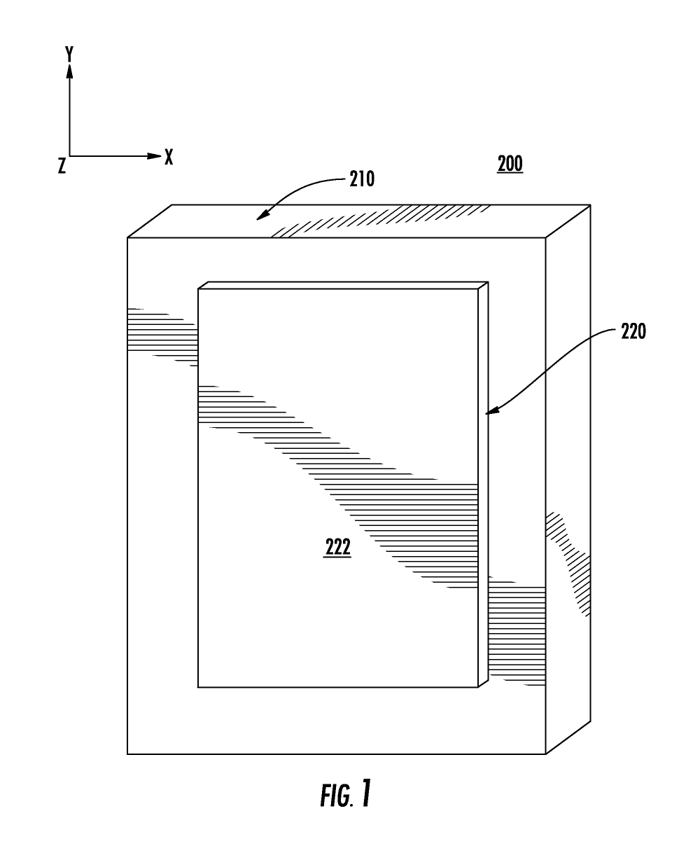

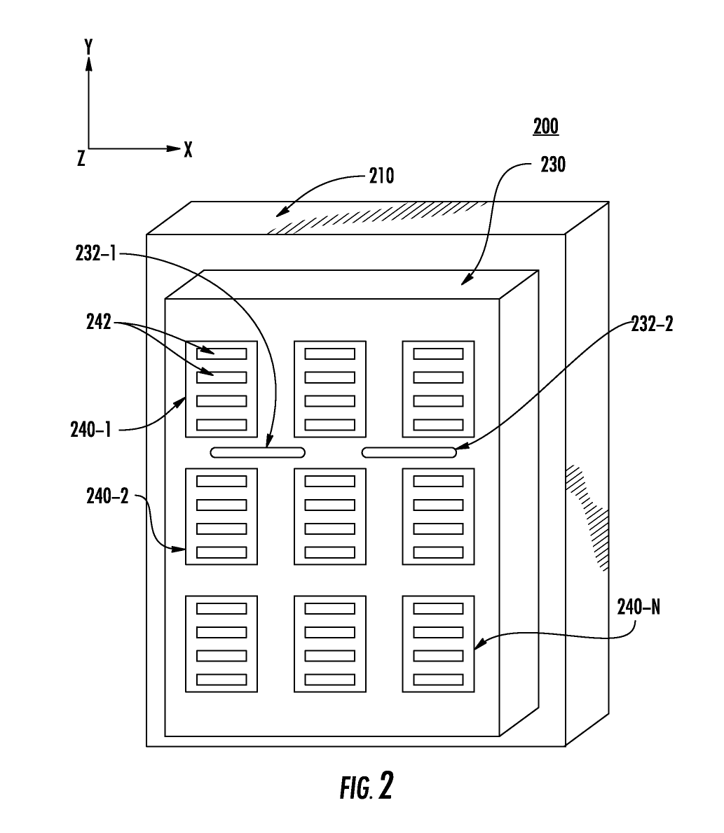

FIGS. 1-2 are perspective views illustrating an example embodiment of components 200. FIG. 1 illustrates a carrier 210 and a workpiece 220 in which ions are to be implanted. During operation, the carrier 210 may be placed on a platen of an ion implant apparatus (not shown). As such, the carrier 210 may be scanned in an x direction or y direction of the Cartesian coordinate system shown. As stated, in some examples, it is desired to mask off portions of the workpiece 220 to block exposure of portions of the workpiece 220 to an ion beam that may be directed toward the components 200. FIG. 2 illustrates the carrier 210 and a mask frame 230 having a number of masks disposed on the carrier.

Turning more specifically to FIG. 1, a carrier 210 is shown including a workpiece 220 disposed on the carrier 210. It is to be appreciated, that although not shown the carrier 210 may include a cavity in which the workpiece 220 is disposed. The workpiece 220 is shown having a target surface 222. More specifically, the target surface 222 is the surface of the workpiece 220 that is to be exposed to the ion beam 108. During operation, the ion beam 108 may be projected towards the target surface 222 (e.g., in the z direction of the Cartesian coordinate system shown) while the carrier is scanned in the x direction or the y direction, or both. In this manner, the target surface 222 may be exposed to the ion beam 108.

It is to be appreciated that the carrier 210 and the workpiece 220 are not drawn to scale. Furthermore, the carrier 210 and the workpiece 220 may in some examples, be rectangular (as shown), square, or circular. Examples are not limited in this context. Furthermore, although a single workpiece 220 is shown, multiple workpieces may be disposed on or in the carrier 210. As such, multiple workpieces may be exposed to the ion beam 108 without needing to remove the carrier 210 and change the workpieces.

Turning more specifically to FIG. 2, the carrier 210 is shown with a mask frame 230 disposed thereon. It is to be appreciated that the mask frame 230 is disposed over the workpiece 220 (not shown) in order to block areas of the workpiece 220 from being exposed to the ion beam 108. The mask frame 230 is depicted having multiple masks 240-1 to 240-N positioned on the mask frame 230. As used herein, a single but unspecific mask may be referred to as mask 240. Furthermore, the masks 240-1 to 240-N collectively may be referred to as masks 240. Additionally, it is to be appreciated, that the number of masks 240 are shown at a quantity to facilitate understanding and is not intended to be limiting. As such, with various examples, more or less masks 240 than depicted may be provided.

In some examples, the masks 240 are disposed on the mask frame 230. With some examples, the masks 240 are disposed in the mask frame 230. Furthermore, each of the masks 240 includes at least one aperture 242. For example, ones of the apertures 242 of the mask 240-1 are denoted with reference designators in FIG. 2. It is to be appreciated that not all apertures 242 are denoted with referenced designators in FIG. 2 for clarity of presentation. Additionally, it is to be appreciated, that the number of apertures 242 are shown at a quantity to facilitate understanding and is not intended to be limiting. Furthermore, it is to be appreciated that the shape of the apertures 242 may vary from implementation to implementations. For example, the apertures 242 may have different shapes, different sizes, different positioning, or the like. Additionally, with some examples, the apertures 242 of one mask 240 may be different than another mask 240.

In some examples, the masks 240 may be fabricated of graphite or other materials. The mask frame 230 may be fabricated of carbon-carbon, graphite, or other materials. With some examples, as stated, multiple workpieces 220 may be disposed on the carrier 210. In such examples, a mask 240 may be positioned over each workpiece 220 on the carrier 210. The carrier 210 may then be disposed on the platen 116. During operation, the ion beam 108 may be projected in the z direction to implant ions in the workpieces 220. More specifically, the ions in the ion beam 108 may be transmitted through the apertures 242 in the masks 240 to be incident on the target surfaces 222. As described above, during operation, the components 200, that is the carrier 210, the workpiece 220, the mask frame 230, and the masks 240 may be scanned in the x direction or the y direction.

In order to ensure that the apertures 242 expose desired areas of the target surface 222, the masks 240 should be aligned with the workpiece 220. As will be appreciated, however, the temperature of the masks 240 may affect the alignment. As such, it may be advantageous to align the masks 240 at the process temperature (e.g., the temperature the masks 240 will have during ion implantation.) Furthermore, the masks 240 may degrade over time due to repeated exposure to the ion beam 108, due to repeatedly being heated and cooled from multiple process cycles, or the like. Degradation of the masks 240 and the temperature of the masks 240 during alignment may affect the ion implantations process. Said differently, the temperature of the masks 240 and the degradation of the masks 240 may affect which areas of the target surface 222 of the workpiece 220 are exposed to the ion beam 108, which affects the manufactured device.

To facilitate measuring the temperature of the masks 240 and monitoring the condition of the masks 240, a first measurement bar 232-1 and a second measurement bar 232-2 may be disposed on the mask frame 232. As used herein, the measurement bars may be referred to collectively as measurement bars 232 while a single but unspecific measurement bar may be referred to as measurement bar 232. It is to be appreciated that the number of measurement bars 232 are shown at a quantity to facilitate understanding. In some examples, more or less measurement bars than depicted may be provided. In some examples, the measurement bars 232 may be placed orthogonal to the x direction (e.g., as shown in the figures) and the dimension measured (described in greater detail below) may correspond with the length of the measurement bars 232. With some examples, the measurement bars 232 may be placed parallel to the x direction and the dimension measured may correspond to the width of the measurement bars. In some examples, a measurement bar 232 may be placed orthogonal to the x direction and another measurement bar 232 may be placed parallel to the x direction.

With some examples, the measurement bars 232 may be made of graphite, carbon-carbon, or other materials. In some examples, the measurement bars 232 may be made of the same material (e.g., graphite) as the masks 240. In some examples, the measurement bars 232 may be made of a different material than the masks 240. In some examples, the measurement bars 232 may be made of a material that has similar thermal characteristics to the material that the masks 240 are made of, including a similar or same thermal expansion coefficient. The measurement bars 232 may be supported or positioned on the mask frame 230 using an insulated pin, such as a screw (not shown). As such, the measurement bars 232 may be easily replaceable and/or added to existing mask frames. With some examples, the insulated pin may be placed at the center of each of the measurement bar 232. With some examples, multiple insulating pins (e.g., positioned at edges of the measurement bars 232, or the like) may be used to fix the measurement bars 232 to the mask frame 230.

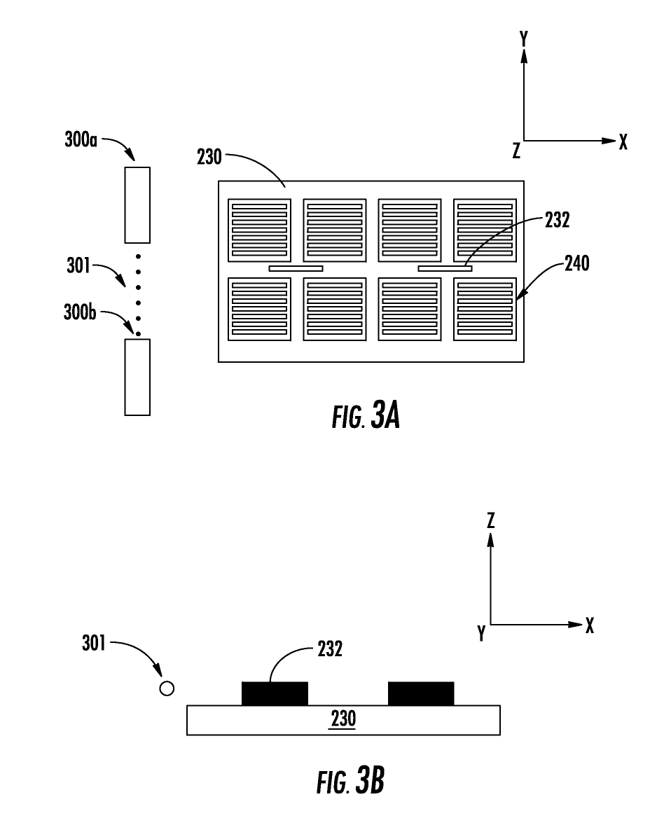

In general, the measurement bars 232 are raised above the surface of the mask frame 230 (refer to FIG. 3B). As the mask frame 230 is scanned in the x direction, the measurement bars 232 may pass through an optical beam (refer to FIGS. 3A-3B) to measure a dimension of the measurement bars 232 and/or identify any inconsistencies in the dimension of the measurement bars 232. As the measurement bars 232 are heated and/or exposed to the ion beam 108, the measurement bars 232 expand. Likewise, the measurement bars 232 shrink as they cool. As the measurement bars 232 degrade, such as, for example, due to impact(s) of the ion beam 108, repeated heating/cooling cycles, or the like, they may break, change position, or otherwise degrade. Measuring the dimensions of the measurement bars 232 can be used to determine the temperature or degree of degradation of the masks 240 and/or or the mask frame 230. As used herein, dimension shall mean length, width, or other aspect of the measurement bars 232 that may be measured by the optical sensors, such as optical sensors 300a, 300b and the controller 310.

FIGS. 3A-3B illustrate block diagrams of the mask frame 230, the masks 240, and the measurement bars 232. FIG. 3A depicts a top view while FIG. 3B depicts a side view. Measurement bars 232 are depicted disposed on the mask frame 230. It is important to note, that for purposes of clarity not all the measurement bars 232 and masks 240 are identified with reference designators in FIGS. 3A-3B. Furthermore, the number of measurement bars 232 and masks 240 are depicted at a quantity to facilitate understanding and it not intended to be limiting.

Turning more specifically to FIG. 3A, optical sensors are also shown adjacent to the mask frame 230. More specifically, the optical sensor 300a and 300b are shown disposed adjacent to the mask frame 230. In some examples, the optical sensors 300a, 300b may be fiber optic sensors including fiber optic cable. For example, the optical sensor 300a may be a fiber optic transmitter and the optical sensor 300b may be a fiber optic receiver. During operation, the optical sensor 300a may project an optical beam 301 (e.g., a laser, a light beam, or the like). The optical sensors 300a, 300b may be positioned such that the optical beam 301 is projected from one optical sensor (e.g., the optical sensor 300a) towards another optical sensor (e.g., the optical sensor 300b). In some examples, the optical sensors 300a, 300b may be positioned such that as the mask frame 230 is scanned in the x direction, the mask frame 230 may travel under the optical sensors 300a, 300b so that the measurement bars 232 pass through the optical beam 301.

More particularly, referring now to FIG. 3B, the mask frame 230 is shown with measurement bars 232 disposed thereon. As can be seen, the measurement bars 232 extend above the surface of the mask frame 230 in the z direction. Accordingly, as the mask frame 230 is translated in the x direction, the mask frame 230 will pass under the optical beam 301 such that the mask frame 230 does not interrupt the optical beam 301 while the measurement bars do interrupt the optical beam 301. The optical sensors 300a, 300b may be spaced apart from each other a distance to enable the measurement bars 232 to pass between the optical sensors 300a, 300b as the mask frame 230 is scanned in the x direction. In some examples, the optical sensors 300a, 300b may be spaced apart approximately an inch.

As stated, during operation as the measurement bars 232 pass through the optical beam 301, the optical beam 301 may be blocked or interrupted. This may occur, for example, as the mask frame 230 is scanned in the x direction. The controller 310 may be configured to measure when the optical beam 301 is blocked and when the optical beam 301 resumes. To accomplish this, a scan encoder position (e.g., the position of the drive assembly 110 or the like) may be recorded when the optical beam 301 is blocked and when the optical beam 301 resumes. These recorded positions may be used to determine the dimension of the measurement bars 232. In one example, the optical resolution of the optical sensors 300a, 300b may be able to detect the dimension of the measurement bars 232 to within 5 μm. Such precision may enable the controller 310 to derive the temperature of the measurement bars 232, the mask frame 230, and/or the masks 240 to within 5° C.

The controller 310 may determine the temperature of the measurement bars 232, the mask frame 230, and/or the masks 240 based at least in part on the measured dimension of the measurement bars 232, the original dimension of the measurement bars 232 (e.g., at room temperature, or the like), and the thermal expansion of the material used to fabricate the measurement bars 232. With some examples, the controller 310 may be configured to derive the temperature of a measurement bar 232 based on the following relationship,

D2=D1(CTE)(ΔT)

In this relationship, D2 is the measured dimension of the measurement bars 232, D1 is the original dimension of the measurement bar 103, CTE is the coefficient of thermal expansion for the material used to fabricate the measurement bar 232 is fabricated, and ΔT is the temperature change between D1 and D2. Accordingly, the temperature of the measurement bar may be determined based on the initial temperature and the derived temperature change. For examples, the controller 310 may determine the temperature of a measurement bar by first determining its current dimension, using the above defined relationship to derive the change in temperature between the starting dimension and the current dimension, and then deriving the current temperature based on the change in temperature and the temperature corresponding to the starting dimension.

Furthermore, the controller 310 may be configured to determine an amount of degradation of the measurement bars 232. For example, if the optical beam 301 is blocked intermittently as it passes across the measurement bar 242, it may be determined that the measurement bar has degraded. Said differently, if the measured dimension of the measurement bar 232 differs from an expected measurement (e.g., differs from the expected measurement by a threshold level, differs from the measured dimension of another measurement bar by a threshold level, or the like) it may indicate that the measurement bar 232 has eroded or been broken off. In such a case, the controller 310 may be configured to output an alert signal to indicate to an operator that the mask frame 230 and/or masks 240 may have degraded.

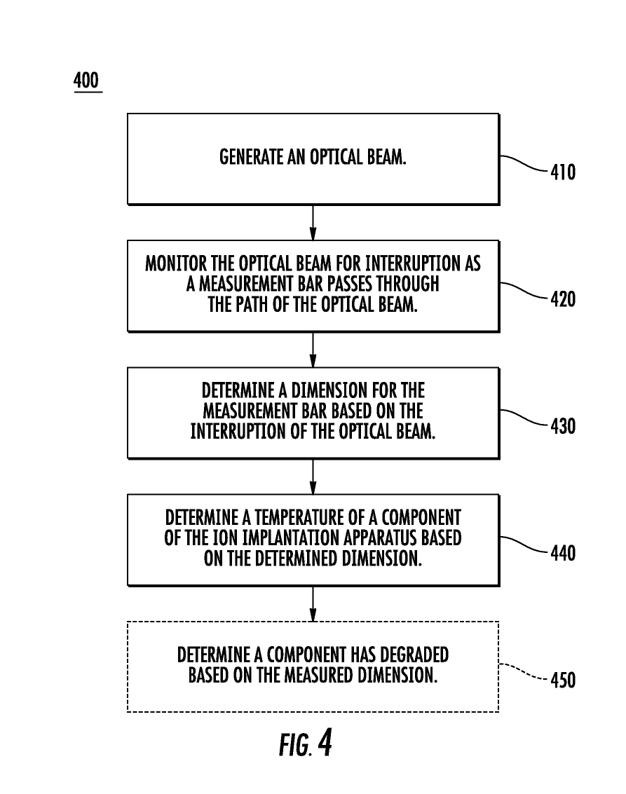

FIG. 4 illustrates a flow chart for a method 400 that may be implemented in an ion implant apparatus to determine a temperature or identify degradation of a component in the ion implant apparatus. Although the method 400 is described with reference to an ion implant apparatus and particularly the measurement bars 232, optical sensors 300a, 300b and controller 310, examples are not limited in this context.

The method 400 may begin at block 410. At block 410, generate an optical beam, the optical sensors 300a, 300b may generate the optical beam 301. More specifically, the optical sensor 300a may transmit the optical beam 301 to the optical sensor 300b. Continuing to block 420, monitor the optical beam for interruption as a measurement bar passes through the path of the optical beam, the controller 310 may monitor the optical beam 301 for interruption as the measurement bar 232 passes through the optical beam 301. Said differently, the controller 310 may monitor the optical beam 301 for interruption as the mask frame 230 is translated in the x direction.

Continuing to block 430, determine a dimension for the measurement bar based on the interruption of the optical beam, the controller 310 may determine a dimension of the measurement bar 232 based on the amount of time the optical beam 301 is interrupted. For example, the controller may determine the dimension of the measurement bar 232 as described above. Continuing to block 440, determine a temperature of a component of the ion implant apparatus based on the determined dimension of the measurement bar, the controller 310 may determine a temperature of the mask frame 230, the masks 240, or the like based on the determined dimension of the measurement bar 232.

Furthermore, the method 400 may optionally include block 450. At block 450, determine a component has degraded based on the measured dimension, the controller 310 may determine that one of the components of the ion implant apparatus (e.g., the mask frame 230, the masks 240, or the like) has degraded based on the determined dimension.

The embodiments described herein may be more accurate than using a laser or infrared thermometer for temperature detection. These embodiments avoid routing wires in the masks or mask frame, which simplifies transport or movement of the masks or mask frame. These embodiments also avoid wireless transmitting devices that may be damaged by an ion beam.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Thus, the claims set forth below should be construed in view of the full breadth and spirit of the present disclosure as described herein.

What is claimed is:

1. A mask frame to hold at least one mask for use in an ion implant process, the mask frame comprising a surface and further including:
a measurement bar disposed on the mask frame, the measurement bar raised above the surface of the mask frame.

2. The mask frame of claim 1, wherein the mask frame is comprised of a first material having a first coefficient of thermal expansion and the measurement bar is comprised of a second material having a second coefficient of thermal expansion the same as the first coefficient of thermal expansion.

3. The mask frame of claim 2, wherein the first material is the same as the second material.

4. The mask frame of claim 1, wherein the measurement bar is a first measurement bar, the mask frame further comprising a second measurement bar disposed on the mask frame, the second measurement bar raised above the surface of the mask frame.

5. The mask frame of claim 4, further comprising at least one mask disposed on the mask frame, wherein the at least one mask is comprised of a first material having a first coefficient of thermal expansion and the first measurement bar and the second measurement bar are comprised of a second material having a second coefficient of thermal expansion, wherein the first coefficient of thermal expansion and the second coefficient of thermal expansion are the same.

6. The mask frame of claim 5, wherein the first material is the same as the second material.

7. An ion implant apparatus comprising:
a platen configured to move in a first direction;
a mask frame to hold at least one mask disposed on the platen, the mask frame having a surface;
a first optical sensor configured to project an optical beam to a second optical sensor; and
a measurement bar disposed on the mask frame, the measurement bar raised above the surface of the mask frame to interrupt the optical beam when the platen moves in the first direction.

8. The ion implant apparatus of claim 7, further comprising a controller to determine a dimension of the measurement bar based at least in part on the measurement bar interrupting the optical beam.

9. The ion implant apparatus of claim 8, wherein the controller is further configured to determine a temperature of the mask frame based at least in part on the determined dimension of the measurement bar.

10. The ion implant apparatus of claim 9, wherein the controller is further configured to determine the mask frame has degraded based at least in part on the determined dimension of the measurement bar.

11. The ion implant apparatus of claim 7, wherein the mask frame is comprised of a first material having a first coefficient of thermal expansion and the measurement bar is comprised of a second material having a second coefficient of thermal expansion, wherein the first coefficient of thermal expansion and the second coefficient of thermal expansion are the same.

12. The ion implant apparatus of claim 7, further comprising one or more masks disposed on the mask frame, wherein the at least one mask is comprised of a first material having a first coefficient of thermal expansion and the measurement bar is comprised of a second material having a second coefficient of thermal expansion, wherein the first coefficient of thermal expansion and the second characteristic thermal expansion are the same.

13. The ion implant apparatus of claim 7, wherein the measurement bar is a first measurement bar, the mask frame further comprising a second measurement bar disposed on the mask frame, the second measurement bar raised above the surface of the mask frame.

14. The ion implant apparatus of claim 13, further comprising a controller to determine a dimension of the measurement bar based at least in part on the measurement bar interrupting the optical beam.

15. The ion implant apparatus of claim 14, wherein the controller is further configured to determine a temperature of the at least one mask based at least in part on the determined dimension of the measurement bar.

16. The ion implant apparatus of claim 15, wherein the controller is further configured to determine the at least one mask has degraded based at least in part on the determined dimension of the measurement bar.

17. A method of measuring a temperature of a component in an ion implant apparatus comprising:
projecting an optical beam from a first optical sensor to a second optical sensor;
scanning a mask frame having a measurement bar disposed therein in a first direction, the measurement bar raised above the surface of the mask frame such that as the mask frame is scanned in the first direction the mask frame does not interrupt the optical beam and the measurement bar interrupts the optical beam;
determining a dimension of the measurement bar based at least in part on the measurement bar interrupting the optical beam; and
determining a temperature of a component in the ion implant apparatus based at least in part on the determined dimension.

18. The method of claim 17, further comprising determining that the component has degraded based at least in part on the determined dimension.

19. The method of claim 17, wherein the component is the mask frame.

20. The method of claim 17, wherein the mask frame has at least one mask disposed thereon, and wherein the component is the at least one mask.
